(19) United States
(12) Patent Application Publication
(10) Pub. No.: US 2023/0105408 A1
(43) Pub. Date: Apr. 6, 2023

(54) HEXAGONAL BORON NITRIDE DEPOSITION

(71) Applicant: Applied Materials, Inc., Santa Clara, CA (US)

(72) Inventors: Zeqing Shen, San Jose, CA (US); Susmit Singha Roy, Campbell, CA (US); Abhijit Basu Mallick, Fremont, CA (US)

(73) Assignee: Applied Materials, Inc., Santa Clara, CA (US)

(21) Appl. No.: 17/943,759

(22) Filed: Sep. 13, 2022

Related U.S. Application Data
(60) Provisional application No. 63/245,508, filed on Sep. 17, 2021.

(51) Int. Cl. C23C 16/34; C23C 16/513; C23C 16/52; H01L 23/528; H01L 23/532; H01L 21/768

(52) U.S. Cl. CPC C23C 16/342; C23C 16/52; C23C 16/513; H01L 21/76831; H01L 21/76832; H01L 23/5283; H01L 23/53295

(57) ABSTRACT

Exemplary semiconductor processing methods may include providing a boron-containing precursor and a nitrogen-containing precursor to a processing region of a semiconductor processing chamber. A substrate may be disposed within the processing region of the semiconductor processing chamber. The methods may include forming a plasma of the boron-containing precursor and the nitrogen-containing precursor in the processing region. A temperature of the substrate may be maintained at less than or about 500° C. The methods may include forming a layer of material on the substrate. The layer of material may include hexagonal boron nitride. The methods include subsequent forming the layer of material on the substrate for a first period of time, halting delivery of the boron-containing precursor. The methods may include maintaining a flow of the nitrogen-containing precursor for a second period of time, and increasing a plasma power while maintaining the flow of the nitrogen-containing precursor.

### CROSS-REFERENCE TO RELATED APPLICATIONS

This application claims the benefit of, and priority to U.S. Provisional Application Serial No. 63/245,508, filed Sep. 17, 2021, which is hereby incorporated by reference in its entirety for all purposes.

### TECHNICAL FIELD

The present technology relates to methods and components for semiconductor processing. More specifically, the present technology relates to methods of producing low-k films with high mechanical strength.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Desirable characteristics in films may vary depending on their application.

Thus, there is a need for improved systems and methods that can be used to produce high quality devices and structures. These and other needs are addressed by the present technology.

### SUMMARY

Exemplary methods of semiconductor processing may include providing a boron-containing precursor and a nitrogen-containing precursor to a processing region of a semiconductor processing chamber. A substrate may be disposed within the processing region of the semiconductor processing chamber. The methods may include forming a plasma of the boron-containing precursor and the nitrogen-containing precursor in the processing region. A temperature of the substrate may be maintained at less than or about 500° C. The methods may include forming a layer of material on the substrate. The layer of material may include hexagonal boron nitride.

In some embodiments, the boron-containing precursor may include at least one of diborane, para-dimethylaminobenzaldehyde, tetramethylammonium bromide, tetraethylammonium bromide, or tris(dimethylamino)borane. The nitrogen-containing precursor may include diatomic nitrogen. A flow rate ratio of the nitrogen-containing precursor to the boron-containing precursor may be maintained at greater than or about 100:1. The methods may include delivering a hydrogen-containing precursor with the boron-containing precursor and the nitrogen-containing precursor. A flow rate ratio of the hydrogen-containing precursor to the boron-containing precursor may be maintained at greater than or about 100:1. A pressure within the semiconductor processing chamber may be maintained at less than or about 10 Torr while forming the layer of material on the substrate. Forming the plasma of the boron-containing precursor and the nitrogen-containing precursor may be performed at a plasma power of less than or about 500 W. The layer of material may be characterized by a boron concentration of greater than or about 25.0 at.%. The boron-containing precursor may include carbon. The layer of material may be characterized by a carbon concentration of less than or about 10.0 at.%. The methods may include subsequent forming the layer of material on the substrate for a first period of time, halting delivery of the boron-containing precursor and maintaining a flow of the nitrogen-containing precursor for a second period of time. The methods may include increasing a plasma power while maintaining the flow of the nitrogen-containing precursor. The methods may include repeating the semiconductor processing method for at least one additional cycle. The substrate may be a dielectric material.

Some embodiments of the present technology may encompass semiconductor processing methods. The methods may include providing a boron-containing precursor and a nitrogen-containing precursor to a processing region of a semiconductor processing chamber. A substrate may be disposed within the processing region of the semiconductor processing chamber. The methods may include forming a plasma of the boron-containing precursor and the nitrogen-containing precursor in the processing region. The methods may include forming a layer of material on the substrate. The layer of material may include hexagonal boron nitride. The methods may include subsequent forming the layer of material on the substrate for a first period of time, halting delivery of the boron-containing precursor. The methods may include maintaining a flow of the nitrogen-containing precursor for a second period of time and increasing a plasma power while maintaining the flow of the nitrogen-containing precursor.

In some embodiments, the boron-containing precursor may include at least one of diborane, para-dimethylaminobenzaldehyde, tetramethylammonium bromide, tetraethylammonium bromide, or tris(dimethylamino)borane. The methods may include repeating the semiconductor processing method for at least one additional cycle. The methods may include increasing the plasma power within the semiconductor processing chamber after halting delivery of the boron-containing precursor comprises increasing the plasma power to greater than or about 600 W. A flow rate ratio of the nitrogen-containing precursor to the boron-containing precursor may be maintained at greater than or about 100:1.

Some embodiments of the present disclosure may encompass semiconductor structures. The semiconductor structures may include a substrate characterized by a first surface and a second surface opposite the first surface. One or more dielectric materials may overly the first surface of the substrate. One or more recesses may be formed within the one or more dielectric materials. A liner material may extend along surfaces defining the one or more recesses. A metal material may be disposed in each recess of the one or more recesses. The metal material may be in contact with the liner material. A layer of material may overly the metal material. The layer of material may include hexagonal boron nitride.

In some embodiments, the layer of material is characterized by a thickness between about 50 Angstrom and 100 Angstrom.

Such technology may provide numerous benefits over conventional systems and techniques. For example, utilizing a boron-containing precursor and a nitrogen-containing precursor according to embodiments of the present disclosure may allow for a layer of hexagonal boron nitride film with a desirable thickness, such as less than 80 nm, that is effective at reducing or preventing diffusion between layers adjacent to the hexagonal boron nitride layer.. Additionally, a layer of hexagonal boron nitride may allow for a desirable low-k film without sacrificing mechanical strength. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations of an exemplary method of semiconductor processing according to some embodiments of the present technology.

FIG. 3 shows an exemplary schematic cross-sectional structure in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Layers of material used to produce semiconductor structures may include conventional low dielectric constant chemical vapor deposited barrier film, which may be referred to as BLok. Low dielectric constant chemical vapor deposited barrier film may be used as an alternative to silicon nitride films. BLok films may be silicon carbide films, and when compared to silicon nitride films, may feature a lower dielectric constant in the barrier film in order to achieve faster, more powerful devices. BLok films, again compared to silicon nitride films, may have a dielectric constant of less than 5, may demonstrate leakage that is six to seven orders of magnitude lower than silicon nitride films, and may feature good adhesion to other films. However, BLok may be relatively thick, such as greater than or about 80 nm. If a film is too thick, such as the thickness of BLok, the reduced size of features within the film may reduce the metal spacing. With reduced metal spacing, line resistance may undesirably increase.

There is an ongoing need for materials with low dielectric constant characteristics that are both mechanically strong and thin enough to avoid increasing line resistance. Hexagonal boron nitride films, which may be used in place of Blok films, may feature thickness less than or about 80 nm, such as about 50 nm. However, conventional methods of forming a hexagonal boron nitride film require temperatures of greater than or about 1,000° C. The present technology may overcome these issues by forming a layer of hexagonal boron nitride instead of the conventional low dielectric constant chemical vapor deposited barrier film. Conventional methods have not been able to form a layer of hexagonal boron nitride as a low dielectric constant chemical vapor deposited barrier due to thermal budgets of other layers previously deposited on the substrate. The produced hexagonal boron nitride materials may be characterized by low dielectric constant values while retaining useful Young’s modulus values, and may be thinner than conventional low dielectric constant chemical vapor deposited barrier films. Further, the produced hexagonal boron nitride materials may be formed at a temperature of less than or about 500° C. and without the aid of any catalyst.

Although the remaining disclosure will routinely identify specific deposition processes utilizing the disclosed technology, and will describe one type of semiconductor processing chamber, it will be readily understood that the processes described are equally applicable to other deposition chambers, as well as processes may be performed in any number of semiconductor processing chambers. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

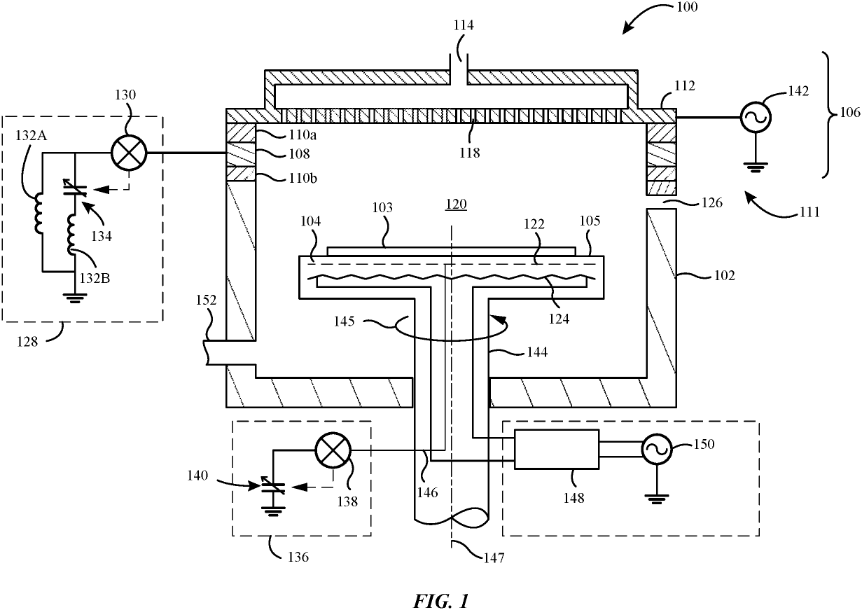

FIG. 1 shows a cross-sectional view of an exemplary semiconductor processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support 104 during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the semiconductor processing chamber 100. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with the surface 105 of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support 104. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support 104 may decline. The second electronic controller 140 may have a similar effect, increasing and decreasing aerial coverage of the plasma over the substrate support 104 as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

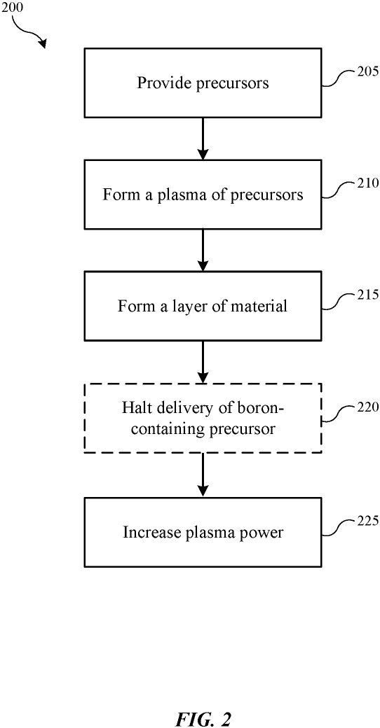

FIG. 2 shows exemplary operations in a processing method 200 according to some embodiments of the present technology. The method 200 may be performed in a variety of processing chambers, including the semiconductor processing chamber 100 described above, as well as any other chambers including non-plasma chambers, in which the operations may be performed. Method 200 may include one or more operations prior to the initiation of the method 200, including front-end processing, deposition, etching, polishing, cleaning, or any other operations that may be performed prior to the described operations. The methods 200 may include a number of optional operations, which may or may not be specifically associated with some embodiments of methods 200 according to embodiments of the present technology. For example, many of the operations are described in order to provide a broader scope of the processes performed, but are not critical to the technology, or may be performed by alternative methodology as will be discussed further below. It is to be understood that the figures illustrate only partial schematic views, and a substrate may contain any number of additional materials and features having a variety of characteristics and aspects as illustrated in the figures.

Method 200 may include a semiconductor processing method that may include operations for forming a material film or layer of material on the substrate, where the film or layer of material is or includes hexagonal boron nitride. The method may include optional operations prior to initiation of method 200, or the method may include additional operations. For example, method 200 may include operations performed prior to the start of the method, including additional deposition, removal, or treatment operations. In some embodiments, method 200 may include providing one or more precursors into a processing chamber at operation 205, which may deliver the precursor or precursors into a processing region of the semiconductor processing chamber where the substrate may be housed. The substrate may include a dielectric material during metallization operations, where one or more layers of metal material may be formed over a structure in back-end-of-line processing. The metal materials may be formed in regions defined in dielectric materials, for example, on which materials according to some embodiments of the present technology may be deposited or formed.

In some embodiments, the precursors may be or include a boron-containing precursor and a nitrogen-containing precursor for producing a low-k dielectric layer, such as hexagonal boron nitride. Boron-containing precursors according to some embodiments of the present technology may include precursors having boron and carbon bonding, and may include linear branched precursors, cyclic precursors, or any number of additional precursors. In some embodiments the precursors may be characterized by certain ratios of carbon and/or oxygen to boron. For example, in some embodiments a ratio of either carbon or oxygen to boron may be greater than or about 1, and may be greater than or about 1.5, greater than or about 2, greater than or about 2.5, greater than or about 3, greater than or about 3.5, greater than or about 4, or more.

Although any number of precursors may be utilized, in some embodiments of the present technology, exemplary boron-containing precursors may include diborane, para-dimethylaminobenzaldehyde, tetramethylammonium bromide, tetraethylammonium bromide, or tris(dimethylamino)borane. Any number of other boron-containing precursors are contemplated, such as boron-containing precursors having carbon bonded to boron and to nitrogen. Exemplary nitrogen-containing precursors may include diatomic nitrogen. In some embodiments, the nitrogen-containing precursor may be ammonia free. As will be further described, it may be easier to form a plasma of ammonia as compared to a plasma of diatomic nitrogen, and the slower cracking of diatomic nitrogen into nitrogen radicals may result in a slower growth rate of the layer of material which may contribute to forming desirable hexagonal boron nitride as opposed to amorphous boron nitride. According to some embodiments, the methods may include delivering a hydrogen-containing precursor with the boron-containing precursor and nitrogen-containing precursor.

Various flow rates of the boron-containing precursor, the nitrogen-containing precursor, and, optionally, the hydrogen-containing precursor may be used depending on the specific semiconductor processing chamber employed. In some embodiments of the present technology, a flow rate ratio of the nitrogen-containing precursor to the boron-containing precursor may be maintained at greater than or about 100:1, and may be maintained at greater than or about 200:1, greater than or about 300:1, greater than or about 400:1, greater than or about 500:1, greater than or about 600:1, greater than or about 700:1, greater than or about 800:1, greater than or about 900:1, greater than or about 1000:1, or higher. The nitrogen-containing precursor may be provided to the processing region of the semiconductor processing chamber 100 at a rate of greater than or about 500 sccm, and may be provided at a rate of greater than or about 750 sccm, greater than or about 1,000 sccm, greater than or about 1,250 sccm, greater than or about 1,500 sccm, greater than or about 1,750 sccm, greater than or about 2,000 sccm, or higher.

Similarly, in some embodiments of the present technology, a flow rate ratio of the hydrogen-containing precursor to the boron-containing precursor may be maintained at greater than or about 100:1, and may be maintained at greater than or about 200:1, greater than or about 300:1, greater than or about 400:1, greater than or about 500:1, greater than or about 600:1, greater than or about 700:1, greater than or about 800:1, greater than or about 900:1, greater than or about 1000:1, or higher. The hydrogen-containing precursor may be provided to the processing region of the semiconductor processing chamber 100 at a rate of greater than or about 500 sccm, and may be provided at a rate of greater than or about 750 sccm, greater than or about 1,000 sccm, greater than or about 1,250 sccm, greater than or about 1,500 sccm, greater than or about 1,750 sccm, greater than or about 2,000 sccm, or higher. In some embodiments, the nitrogen-containing precursor and the hydrogen-containing precursor may be provided to the semiconductor processing chamber 100 at an equal flow rate.

By controlling the flow rates, the layer of material may be formed at a rate such that the layer desirably contains hexagonal boron nitride. For example, a low flow rate of boron-containing precursor may result in greater nitrogen incorporation in the layer and the resulting hexagonal boron nitride layer growing at a slow rate. The ratio of nitrogen to boron in the layer may be greater than or about 1:3, and may be greater than or about 1:2, greater than or about 2:3, greater than or about 1:1, or higher. In embodiments, the flow rate of the boron-containing precursor may be less than or about 20 sccm, and may be less than or about 15 sccm, less than or about 10 sccm, less than or about 9 sccm, less than or about 8 sccm, less than or aout 7 sccm, less than or about 6 sccm, less than or about 5 sccm, less than or about 4 sccm, less than or about 3 sccm, less than or about 2 sccm, or lower. Further, while providing a hydrogen-containing precursor is not necessary to form a hexagonal boron nitride, the hydrogen may serve to etch and remove portions of the hexagonal boron nitride that may have low mechanical strength or high dielectric characteristics.

At operation 210, a plasma may be formed of the boron-containing precursor and the nitrogen-containing precursor within the processing region. The precursor or precursors may be delivered to the processing region of the chamber, and a plasma may be formed. The plasma may be generated such as by providing RF power to the faceplate to generate a plasma within processing region, although any other processing chamber capable of producing plasma may similarly be used. Forming the plasma of the boron-containing precursor and the nitrogen-containing precursor may be performed at a plasma power of less than or about 500 W, and may formed at a plasma power of less than or about 450 W, less than or about 400 W, less than or about 350 W, less than or about 300 W, less than or about 250 W, or lower. Using a plasma power of less than or about 500 W may slow the deposition rate of the layer of material on the substrate, which may result in a more uniformed structure with less defects within the layer of material. That is, the layer of material, with a slow deposition rate, may be a harder material without sacrificing dielectric characteristics. The deposition rate of the layer of material may be slower due to the hexagonal structure, as compared to other structures such as an amorphous or cubic structure, and to the nitrogen to boron ratio in the layer of material. By using precursors and flow rates specified in the present disclosure, the precursors may slowly dissociate into plasma effluents and, therefore, may slowly deposit on the substrate and form the layer of material.

A substrate 305 may be disposed within the processing region of the semiconductor processing chamber 100. The substrate 305 may be contacted with plasma effluents of the precursors, and favorable terminations may be produced. The use of diatomic nitrogen as the nitrogen-containing precursor may result in the plasma being formed at a slower rate. The individual nitrogen atoms in diatomic nitrogen are bonded via three covalent bonds and slowly break to form individual nitrogen radicals. The slow generation of nitrogen plasma from diatomic nitrogen, as compared to nitrogen-containing precursors not having three covalent bonds attached to the nitrogen radical, may slow the rate at which the layer of material may form on the substrate 305. If the growth rate of the layer of material is too fast, amorphous boron nitride may be formed instead of the desirable hexagonal boron nitride. Also, as previously described, using a plasma power of less than or about 500 W may contribute to slowing the deposition rate of the layer of material on the substrate 305, which may result in a more uniformed structure with less defects within the layer of material.

The deposition may be performed at substrate or pedestal temperatures less than or about 500° C., which may be the thermal budget at back end of line processing, for example. In some embodiments the deposition may occur at temperatures greater than or about 200° C., greater than or about 225° C., greater than or about 250° C., greater than or about 275° C., greater than or about 300° C., greater than or about 325° C., greater than or about 350° C., greater than or about 375° C., greater than or about 400° C., greater than or about 425° C., greater than or about 450° C., greater than or about 475° C., or higher. Temperatures less than or about 500° C. may be possible due to the use of plasma power, such as high frequency plasma power. In conventional methods, plasma power may not be utilized and may require higher temperatures to form hexagonal boron nitride films. Deposition may occur at pressures less than or about 10 Torr, and may occur at a pressure less than or about 9 Torr, less than or about 8 Torr, less than or about 7 Torr, less than or about 6 Torr, less than or about 5 Torr, less than or about 4 Torr, less than or about 3 Torr, less than about 2 Torr, or lower. Deposition may occur at pressures greater than or about 0.5 Torr, greater than or about 1 Torr, greater than or about 2 Torr, greater than or about 3 Torr, greater than or about 4 Torr, greater than or about 5 Torr, or greater.

Effluents of the plasma of the boron-containing precursor and nitrogen-containing precursor may be deposited on the substrate at operation 215, which may produce a boron-and-nitrogen-containing material, such as a hexagonal boron nitride. By utilizing a low-power plasma, such as a plasma formed at a plasma power of less than or about 500 W, the amount of dissociation of the precursors may reduce as cracking of the boron-containing precursor and nitrogen-containing precursor may require additional energy and time. This may decrease a deposition rate of the material and slow the growth rate of the material on the substrate 305. A decrease in the deposition rate of the material may assist in forming hexagonal boron nitride at a temperature below the thermal budget. Although embodiments of the present technology may encompass additional treatments subsequent deposition, the as-deposited characteristics of the film may include a range of improvements over conventional technology.

According to some embodiments, flow of the boron-containing precursor may be halted at operation 220, and in some embodiments flow of the nitrogen and/or hydrogen precursors may continue. Halting the flow of the boron-containing precursor may allow the layer of material already formed on the substrate to further process. When the boron-containing precursor is not being provided, the nitrogen-containing precursor, and the optional hydrogen-containing precursor, may effectively remove any of the layer of material that is lower quality. The lower quality material that may be removed by the nitrogen-containing precursor, and the optional hydrogen-containing precursor, may be material that did not form as well-layered material. The lower quality material may be more readily removed at low power without etching or removing the desirable high quality material, such as the hexagonal boron nitride, that is structurally intact and more resistant to the nitrogen-containing precursor, and the optional hydrogen-containing precursor.

At operation 225, the plasma power in the processing region of the semiconductor processing chamber may be increased. The plasma power may be increased at operation 225 after the flow of the boron-containing precursor has been reduced. In some embodiments, the plasma power may be increased at operation 225 after flow of the boron-containing precursor has been halted and flow of the nitrogen-containing precursor has been maintained. During operation 225, the plasma power may be increased to greater than or about 600 W, and may be increased to greater than or about 700 W, greater than or about 800 W, greater than or about 900 W, greater than or about 1000 W, or higher. Increasing the plasma power may densify and realign the film to improve the mechanical strength of the layer of material on the substrate. At operation 225, some portions of the layer of material on the substrate may transition from an amorphous or cubic structure to a hexagonal structure, such as the layer of material may be characterized as a well-oriented layered structure of hexagonal boron nitride. With the material being realigned, the material may be more ordered, with less defects, and may reduce or eliminate diffusion of atoms or molecules through the layer.

According to the present technology, hexagonal boron nitride materials may be produced that may be characterized by a dielectric constant of less than or about 4.00, and may be less than or about 3.95, less than or about 3.90, less than or about 3.85, less than or about 3.80, less than or about 3.75, less than or about 3.70, less than or about 3.65, less than or about 3.60, less than or about 3.55, less than or about 3.50, less than or about 3.45, less than or about 3.40, less than or about 3.35, less than or about 3.30, less than or about 3.25, less than or about 3.20, less than or about 3.15, less than or about 3.10, less than or about 3.05, less than or about 3.00, or less. Conventional methods of forming layers of materials to be used as a low dielectric constant chemical vapor deposited barrier film may sacrifice mechanical strength properties for a low dielectric constant. Further, hexagonal boron nitride may not be suitable as a barrier film as conventional methods of developing the film may be above thermal budgets in semiconductor processing. As described previously, conventional methods of depositing hexagonal boron nitride may require temperatures greater than or about 1000° C., which may be much higher than the thermal budget, as the conventional methods do not utilize plasma power, such as high frequency plasma power, to deposit the hexagonal boron nitride. Conversely, the present inventors have identified that using plasma power, such as high frequency plasma power, may allow the temperature necessary to form hexagonal boron nitride to be much lower, and within thermal budgets.

Dielectric constant may be related to material properties of the film. Conventionally, the lower the dielectric constant, the lower the Young’s modulus of the film produced. However, by producing films according to some embodiments of the present technology, Young’s modulus may be maintained higher than would otherwise occur in conventional technologies capable of producing films with corresponding as-deposited dielectric constant values. For example, in some embodiments, the present technology may produce materials characterized by a Young’s modulus of greater than or about 55 Gpa, and may be characterized by a Young’s modulus of greater than or about 56 Gpa, greater than or about 57 Gpa, greater than or about 58 Gpa, greater than or about 59 Gpa, greater than or about 60 Gpa, greater than or about 61 Gpa, greater than or about 62 Gpa, greater than or about 63 Gpa, greater than or about 64 Gpa, greater than or about 65 Gpa, greater than or about 66 Gpa, greater than or about 67 Gpa, greater than or about 68 Gpa, greater than or about 69 Gpa, greater than or about 70 Gpa, or higher. Consequently, the present technology may produce films characterized by a lower dielectric constant, while maintaining higher Young’s modulus of the materials. It is noted that in embodiments using a boron-containing precursor having a higher amount of carbon, the Young’s modulus may be lower than embodiments using a boron-containing precursor having a lower amount of carbon. Depending on the application and desired characteristics, it may be desirable to select a boron-containing precursor with a lower amount of carbon to limit the amount of carbon in the layer of material formed on the substrate 305.

The material characteristics produced by embodiments of the present technology may be related to an amount of boron incorporated within the layer. For example, in some embodiments, as-deposited materials produced according to the present technology may be characterized by a boron percentage incorporated or retained within the film of greater than or about 25.0 at.%, and may be characterized by a boron incorporation within the film of greater than or about 27.5 at.%, greater than or about 30.0 at.%, greater than or about 32.5 at.%, greater than or about 35.0 at.%, greater than or about 37.5 at.%, greater than or about 40.0 at.%, greater than or about 42.5 at.%, greater than or about 45.0 at.%, greater than or about 47.5 at.%, or higher.

Additionally, a percentage of carbon incorporated within the layer may be less than or about 10.0 at.% in the as-deposited materials, and may be greater than or about 9.0 at.%, greater than or about 8.0 at.%, greater than or about 7.0 at.%, greater than or about 6.0 at.%, greater than or about 5.0 at.%, greater than or about 4.0 at.%, greater than or about 3.0 at.%, greater than or about 2.0 at.%, greater than or about 1.0 at.%, or lower. Lower amounts of carbon in the layer of material may boost material characteristics, such as the Young’s modulus, of the layer of material. Selection of the boron-containing precursor, and the amount of carbon in the precursor, may affect the resulting amount of carbon in the layer of material. The specific boron-containing precursor or precursors used may affect all material properties of the layer of material. For example, a boron-containing precursor also containing a large amount of carbon may reduce the Young’s modulus, such as by halving the Young’s modulus. However, by utilizing low-power plasma along with other processing characteristics according to embodiments of the present technology, low-k dielectric materials may be produced, which may be characterized by an increased Young’s modulus, among other material properties.

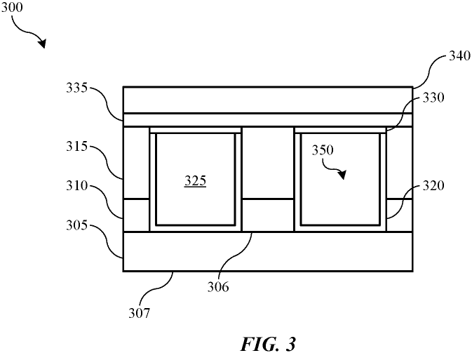

FIG. 3 shows an exemplary schematic cross-sectional structure 300 in which material layers are included and produced according to some embodiments of the present technology. The structure 300 may include multiple layers deposited on a substrate 305. The substrate 305 may include a first surface 306 and a second surface 307 opposite the first surface 306. The substrate may be, for example, silicon. One or more dielectric materials may overly the first surface 306 of the substrate 305. The one or more dielectric materials may include layers such as a first low-dielectric barrier layer 310 and a second low-dielectric barrier layer 340. The one or more dielectric materials, such as the first low-dielectric barrier layer 310 and the second low-dielectric barrier layer 340, may include, but are not limited to oxide materials, such as silicon oxide, or doped oxides with fluorine, carbon, or other low-k materials that may be used in processing. One or more recesses 350 may be formed within the one or more dielectric materials. The layers may also include a low-dielectric material 315, a liner material 320, a metal material 325, and a barrier material 330. The low-dielectric material 315 may be a silicon-containing material such as, for example, silicon oxide or silicon nitride.

The liner material 320 may extend along surfaces defining the one or more recesses 350. The liner material 320 may define an opening. In some embodiments, the liner material 320 may be tantalum nitride. The liner material 320 may be a material that is conformal on dielectric material when deposited. The liner material 320 may include, but is not limited to, tantalum nitride or titanium nitride. The metal material 325 may be disposed in each recess of the one or more recesses 350. The metal material 325 may be in contact with the liner material 320, and may be any number of metals such as copper, cobalt, tungsten, or other metal materials. The barrier material 330 may be, for example, cobalt. The barrier material 330 may be a material that is selective on metal material when deposited.

A hexagonal boron nitride layer 335, such as the hexagonal boron nitride material described in the present disclosure, may be formed over the low-dielectric material 315, the metal material 325, the barrier material 330, or combinations thereof. Thus, the hexagonal boron nitride layer 335 may be characterized as a blanket that covers all metals and dielectric material. In embodiments, the hexagonal boron nitride layer 335 may have a thickness between about 50 Angstrom and about 100 Angstrom, such as between about 50 Angstrom and about 80 Angstrom. As previously discussed the hexagonal boron nitride material may have desirable characteristics, such as a low dielectric constant without sacrificing mechanical strength. Additionally, the hexagonal boron nitride material may reduce or eliminate diffusion of atoms and molecules between layers separated by the hexagonal boron nitride layer, such as the second low-dielectric barrier layer 340 and the low-dielectric material 315 and/or the barrier material 330.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a boron-containing precursor” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a boron-containing precursor and a nitrogen-containing precursor to a processing region of a semiconductor processing chamber, wherein a substrate is disposed within the processing region of the semiconductor processing chamber;
forming a plasma of the boron-containing precursor and the nitrogen-containing precursor in the processing region, wherein a temperature of the substrate is maintained at less than or about 500° C.; and
forming a layer of material on the substrate, wherein the layer of material comprises hexagonal boron nitride.

2. The semiconductor processing method of claim 1, wherein the boron-containing precursor comprises at least one of diborane, para-dimethylaminobenzaldehyde, tetramethylammonium bromide, tetraethylammonium bromide, or tris(dimethylamino)borane.

3. The semiconductor processing method of claim 1, wherein the nitrogen-containing precursor comprises diatomic nitrogen.

4. The semiconductor processing method of claim 1, wherein a flow rate ratio of the nitrogen-containing precursor to the boron-containing precursor is maintained at greater than or about 100:1.

5. The semiconductor processing method of claim 4, further comprising:
delivering a hydrogen-containing precursor with the boron-containing precursor and the nitrogen-containing precursor, wherein a flow rate ratio of the hydrogen-containing precursor to the boron-containing precursor is maintained at greater than or about 100:1.

6. The semiconductor processing method of claim 1, wherein a pressure within the semiconductor processing chamber is maintained at less than or about 10 Torr while forming the layer of material on the substrate.

7. The semiconductor processing method of claim 1, wherein forming the plasma of the boron-containing precursor and the nitrogen-containing precursor is performed at a plasma power of less than or about 500 W.

8. The semiconductor processing method of claim 1, wherein the layer of material is characterized by a boron concentration of greater than or about 25.0 at.%.

9. The semiconductor processing method of claim 8, wherein the boron-containing precursor comprises carbon, and wherein the layer of material is further characterized by a carbon concentration of less than or about 10.0 at.%.

10. The semiconductor processing method of claim 1, further comprising:
subsequent forming the layer of material on the substrate for a first period of time, halting delivery of the boron-containing precursor; and
maintaining a flow of the nitrogen-containing precursor for a second period of time.

11. The semiconductor processing method of claim 10, further comprising:
increasing a plasma power while maintaining the flow of the nitrogen-containing precursor.

12. The semiconductor processing method of claim 11, further comprising:
repeating the semiconductor processing method for at least one additional cycle.

13. The semiconductor processing method of claim 1, wherein the substrate is a dielectric material.

14. A semiconductor processing method comprising:
providing a boron-containing precursor and a nitrogen-containing precursor to a processing region of a semiconductor processing chamber, wherein a substrate is disposed within the processing region of the semiconductor processing chamber;
forming a plasma of the boron-containing precursor and the nitrogen-containing precursor in the processing region;
forming a layer of material on the substrate, wherein the layer of material comprises hexagonal boron nitride;
subsequent forming the layer of material on the substrate for a first period of time, halting delivery of the boron-containing precursor;
maintaining a flow of the nitrogen-containing precursor for a second period of time; and
increasing a plasma power while maintaining the flow of the nitrogen-containing precursor.

15. The semiconductor processing method of claim 14, wherein the boron-containing precursor comprises at least one of diborane, para-dimethylaminobenzaldehyde, tetramethylammonium bromide, tetraethylammonium bromide, or tris(dimethylamino)borane.

16. The semiconductor processing method of claim 14, further comprising:
repeating the semiconductor processing method for at least one additional cycle.

17. The semiconductor processing method of claim 14, wherein increasing the plasma power within the semiconductor processing chamber after halting delivery of the boron-containing precursor comprises increasing the plasma power to greater than or about 600 W.

18. The semiconductor processing method of claim 14, wherein a flow rate ratio of the nitrogen-containing precursor to the boron-containing precursor is maintained at greater than or about 100:1.

19. A semiconductor structure comprising:
a substrate characterized by a first surface and a second surface opposite the first surface;
one or more dielectric materials overlying the first surface of the substrate, wherein one or more recesses are formed within the one or more dielectric materials;
a liner material extending along surfaces defining the one or more recesses;
a metal material disposed in each recess of the one or more recesses, the metal material in contact with the liner material; and
a layer of material overlying the metal material, wherein the layer of material comprises hexagonal boron nitride.

20. The semiconductor structure of claim 19, wherein the layer of material is characterized by a thickness between about 50 Angstrom and 100 Angstrom.
